(19) United States
(12) Patent Application Publication
(10) Pub. No.: US 2026/0173940 A1
(43) Pub. Date: Jun. 18, 2026

(54) UNDER-BUMP METALLIZATION STRUCTURE AND METHODS OF FORMING THE SAME

(71) Applicant: Taiwan Semiconductor Manufacturing Company Limited, Hsinchu (TW)

(72) Inventors: Jui Shen Chang, Taichung City (TW); Chung-Yu Chiu, Hsinchu (TW); Chen-Nan Chiu, Hsinchu City (TW); Yao-Chun Chuang, Hsinchu City (TW); Chang-Jung Hsueh, Taipei (TW)

(21) Appl. No.: 18/979,971

(22) Filed: Dec. 13, 2024

(51) Int. Cl. H01L 23/00; H01L 23/29

(52) U.S. Cl. CPC H10W 72/20; H10W 72/012; H10W 72/019; H10W 72/90; H10W 72/01257; H10W 72/01271; H10W 72/01935; H10W 72/01938; H10W 72/222; H10W 72/224; H10W 72/251; H10W 72/29; H10W 72/934; H10W 72/952; H10W 74/47

(57) ABSTRACT

A semiconductor structure and methods for forming the same. In some embodiments, a semiconductor structure includes an under-bump metallization structure where the under-bump metallization structure includes a recess. Further, the semiconductor structure includes a ball structure is located above the recess of the under-bump metallization structure. Additionally, the semiconductor structure includes an intermetallic compound structure located above the under-bump metallization structure and surrounding the ball structure and a solder portion located above the intermetal compound structure.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

In addition to smaller electronic components, improvements to the packaging of components seek to provide improved performance. For example, the use of copper core solder balls have the potential to enhance the performance of electromigration through their ability to reduce current crowding. However, the presence of the copper solder balls may lead to a decrease in solder volume. This decrease in solder volume may result in decreases in both board level reliability and mechanical strength.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example vertical cross-sectional view of an under-bump metallization structure according to various embodiments of the present disclosure.

FIG. 2 is an example vertical cross-sectional view of an intermediate structure that includes a redistribution layer and a polyimide layer according to various embodiments of the present disclosure.

FIG. 3 is an example vertical cross-sectional view of an intermediate structure after forming a cavity within the polyimide layer according to various embodiments of the present disclosure.

FIG. 4 is an example vertical cross-sectional view of an intermediate structure after forming a seed layer according to various embodiments of the present disclosure.

FIG. 5 is an example vertical cross-sectional view of an intermediate structure after forming a photoresist layer according to various embodiments of the present disclosure.

FIG. 6 is an example vertical cross-sectional view of an intermediate structure after photoresist patterning and developing according to various embodiments of the present disclosure.

FIG. 7 is an example vertical cross-sectional view of an intermediate structure after platting a high-texture material according to various embodiments of the present disclosure.

FIG. 8 is an example vertical cross-sectional view of an intermediate structure after photoresist stripping according to various embodiments of the present disclosure.

FIG. 9 is an example vertical cross-sectional view of an intermediate structure after performing a seed layer etch according to various embodiments of the present disclosure.

FIG. 10 is an example vertical cross-sectional view of an intermediate structure after connecting a solder ball to the under-bump metallization structure according to various embodiments of the present disclosure.

FIG. 11 is an example vertical cross-sectional view of an intermediate structure after performing an annealing process to form an intermetallic compound connection according to various embodiments of the present disclosure.

FIG. 12A is an example vertical cross-sectional view illustrating various dimensions of the semiconductor structure according to various embodiments of the present disclosure.

FIG. 12B is an example top view of the structure in FIG. 12A according to various embodiments of the present disclosure.

FIG. 13A is an example vertical cross-sectional view illustrating an alternative ball structure according to various embodiments of the present disclosure.

FIG. 13B is an example top view of the ball structure in FIG. 13A according to various embodiments of the present disclosure.

FIG. 14 is an example vertical cross-sectional view illustrating another alternative ball structure according to various embodiments of the present disclosure.

FIG. 15 is a flowchart illustrating a method of forming an under-bump metallization and ball structure with a connected intermetallic compound structure according to various embodiments of the present disclosure.

FIG. 16 is a flowchart illustrating a method of forming an under-bump metallization pedestal according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Ordinals such as “first,” “second,” “third,” “last” etc. are not an inherent part of a name of any element, and are used only for the purpose of individually identifying multiple elements having the same, or similar, characteristics, and thus, different ordinals may be used for a same element across the specification and the claims. For example, a second element in the specification may be referred to as a first element in the claims.

Elements with the same reference numerals refer to the same element, and are presumed to have the same material composition and the same thickness range unless expressly indicated otherwise. As used herein, an element or a system “configured for” a function or an operation or “configured to” provide or perform a function or an operation.

Wafer level semiconductor packages include integrated circuits at the wafer level. The wafer may be diced (singulated) to create individual units. A wafer level semiconductor typically includes a first tier structure that may include a substrate, a polyimide layer, and a redistribution layer (RDL) with a dielectric layer located above and below the RDL. Additionally, the first tier may include bonding pads, such as aluminum pads, located within the various layers.

The first tier may be connected to other elements, components and/or tiers through solder balls placed over the bonding pads. The solder balls may be located at specified locations above under-bump metallization structures. The under-bump metallization layer may include a thin metal layer followed by an adhesion layer. The adhesion layer enhances the adhesion of the solder ball to the metal layer surface. The solder ball may include a wetting portion (e.g., copper) surrounded by a barrier layer (e.g., nickel) surrounded by an intermetallic compound structure and further surrounded by solder material.

The wetting portion may be formed of a conductive material, such as copper. Such conductive materials may provide improved electrical conductivity and heat dissipation characteristics. The barrier layer may prevent diffusion of the conductive material that makes up the wetting portion into the solder material. In addition, the barrier layer may provide oxidation resistance. The intermetallic compound structure may provide an interface between the wetting portion and the solder material to allow a strong metallurgical bond between the wetting portion and the solder material while providing mechanical stability. Additionally, the intermetallic compound structure may enhance electrical conductivity by providing additional conductive material and structural integrity to mitigate against mechanical stress that may result from thermal cycling as well as rough handling of the semiconductor package.

While the solder balls provide electrical connection between the first tier and other elements, components and or tiers, solder ball drift is a problem that may cause challenges when using solder balls as an electrical connection. For example, solder ball drift may cause surface tension imbalance, non-uniform heating, and substrate warpage. Additionally, solder ball drift may decrease the reliability of the semiconductor structure. In more detail, misalignment of the solder ball in relation to the under-bump metallization due to solder ball drift may lead to poor electrical connections resulting in intermittent or permanent electrical failures. Further, solder ball drift may cause uneven distribution of mechanical stress leading to cracks and/or fractures in the solder balls. Even further, misaligned solder balls due to solder ball drift may affect the thermal conductivity of the semiconductor structure resulting in overheating and reduced lifespan of the structure. As a result of any and all of these challenges, solder ball drift may reduce the yield by increasing the rejection rate of the solder ball during manufacturing and reducing overall yield resulting in increased costs.

Embodiments of the present disclosure relate to a semiconductor structure that includes an under-bump metallization structure with a pedestal-like structure located below the solder ball structure connected by an intermetallic compound structure. The under-bump metallization structure may include a recess portion. A solder ball structure may be located above the recess of the under-bump metallization structure and an intermetallic compound structure may surround the solder ball structure. The intermetallic compound structure may be located above and connected to the under-bump metallization structure. A solder portion may be located above the intermetallic compound structure surrounding the ball structure.

Various embodiments disclosed herein may provide various advantages and improvements. For example, various embodiments disclosed herein may provide a under-bump metallization structure that ensures a uniform solder ball structure position. Additionally, the embodiment under-bump metallization structures may enhance the alignment between the under-bump metallization structure and the solder ball structure. Further, various embodiments enhance the performance of electromigration due to the ability of the under-bump metallization structure ability to reduce current crowding. Additionally, the various embodiment under-bump metallization structures may provide additional mechanical strength to reduce cracking and fracturing of the solder material. Various embodiments disclosed herein may further utilize a high-texture material to form the under-bump materialization structure which mitigates against side wall wetting and promotes the solder material to surround the conductive portion of the solder ball structure. During an annealing process, the intermetallic compound structure directly connects with the under-bump metallization structure due to the high-texture material because the high-texture material exhibits a faster diffusion rate resulting in an immediate connection. Therefore, various embodiments disclosed herein improve semiconductor structure reliability in particular improves the mechanical strength of the semiconductor structure.

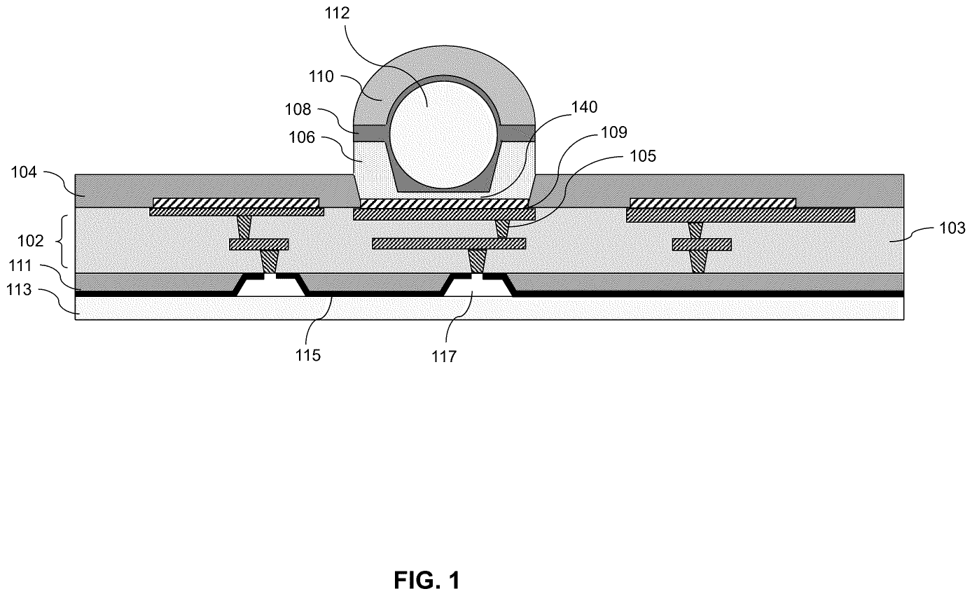

Referring now to figures, FIG. 1 illustrates an example vertical cross-sectional view of an embodiment of an under-bump metallization (UBM) structure 106 with a connected intermetallic compound structure (IMC) 108 that fixes a position of a ball structure 112 and ensures uniform distribution of the solder material 110 around the ball structure 112. The semiconductor structure includes a silicon substrate 113 with a bonding pad 117 connecting to a redistribution layer (RDL) 102. A passivation layer 115 may be located above the silicon substrate 113 and partially surrounding the bonding pad 117 and separates the silicon substrate 113 from a polyimide layer 111.

The RDL 102 may include a dielectric layer 103 with redistribution wiring interconnects 105 formed within the dielectric layer 103 and bonding pads 109 located above the redistribution wiring interconnects 105. The dielectric layer 103 may include a respective dielectric polymer material such as polyimide (PI), benzocyclobutene (BCB), or polybenzobisoxazole (PBO). The dielectric layer 103 may be formed by spin coating and drying of the respective dielectric polymer material. The thickness of the dielectric layer 103 may be in a range from 2 microns to 40 microns, such as from 4 microns to 20 microns. The dielectric layer 103 may be patterned, for example, by applying and patterning a respective photoresist layer thereabove, and by transferring the pattern in the photoresist layer into the dielectric layer 103 using an etch process such as an anisotropic etch process. The photoresist layer may be subsequently removed, for example, by ashing.

The redistribution wiring interconnects 105 and the bonding pads 109 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the redistribution wiring interconnects 105 may include copper, nickel, or copper and nickel. The thickness of the metallic fill material that is deposited for each redistribution wiring interconnect 105 may be in a range from 2 microns to 40 microns, such as from 4 microns to 10 microns, although lesser or greater thicknesses may also be used. The total number of levels of wiring (i.e., the levels of the redistribution wiring interconnects 105) may be in a range from 1 to 10.

The RDL 102 may enhance functionality and integration of components within a semiconductor device. For example, the RDL 102 may provide electrical connections between layers of the semiconductor structure and further distribute electrical connections and allowing optimization of component locations within the package. The RDL 102 may further enable advanced packaging by integrating multiple dies into a single semiconductor device resulting in a reduced overall footprint while improving performance. Further, the RDL 102 provides signal routing that distributes power efficiently and therefore improves overall efficiency for the semiconductor device when multiple components are integrated. Additionally, the RDL 102 facilitates bonding between different components and may manage and improve thermal stress during mounting and utilization of the device.

A polyimide layer 104 may be located above the RDL 102. The polyimide layer 104 may be formed of silicon dioxide, silicon nitride, aluminum oxide, hafnium oxide, or other appropriate materials. The polyimide layer 104 may protect the RDL 102 from environmental damage, reduce surface states, and improve overall reliability and performance. For example, the polyimide layer 104 may provide insulating properties that protect the underlying layers. The protective properties of the polyimide layer 104 may protect the underlying layers against moisture, ions, dust, chemicals, and contaminates. Further, the polyimide layer 104 may reduce the number of surface states that trap charge carriers and thereby mitigate device degradation. By protecting the underlying layers and reducing the surface states, the polyimide layer 104 may improve overall reliability and longevity of the semiconductor structure. Additionally, the polyimide layer 104 may have a high dielectric constant and provide polyimide properties therefore reducing surface recombination. The polyimide layer 104 may also improve thermal stability by mitigating thermal concerns during operation of different components within the semiconductor structure.

A under-bump metallization (UBM) structure 106 may be formed over and through the polyimide layer 104 connecting to the RDL 102. The UBM structure 106 may be formed of a high-texture material. The high-texture material may be copper, aluminum, gold, siler, or other appropriate materials. In some embodiments the high-texture material has a (111) orientation, (100) orientation, (001) orientation, or other appropriate orientations with high-texture. As an example, Cu(111) may be referred to as a “textured structure”, “textured copper”, “high-texture structure” or “high-texture copper”. A surface of the Cu(111) may be highly textured (e.g., have a high roughness). However, the roughness of the surface may be modified (e.g., by adjusting the parameter of the plating process) to be close to that of a Cu(100) layer (e.g., a non-textured structure) which may have a higher amount of random copper than a Cu(111) layer. The high-texture material of the UBM structure 106 may reduce and prevent side wall wetting effects.

In some embodiments, the high-texture material of the UBM structure 106 may be detected and defined by using electron backscatter diffraction (EBSD) and/or scanning electron microscopy (SEM). SEM is an imaging technique that examines the structure of a surface at high magnifications. SEM uses a focused beam of electrons to scan the surface and detects the reflected beam of electrons from the surface. The reflected beams are analyzed to create detailed images of the topology of the surface structure. Additionally, EBSD may be used during SEM to analyze the crystallographic structure of materials. In more detail, EBSD sends an electron beam directed at the surface where the surface is tilted which causes the electron beam to scatter and form diffraction patterns. The diffraction patterns are analyzed to determine the surface orientation and other structural details of the surface. In an embodiment, SEM and EBSD detect the high-texture material of the UBM structure 106 (e.g., copper (111) orientation).

The IMC structure 108 may be located above the UBM structure 106. In more detail, the IMC structure 108 may be in direct contact with the UBM structure 106 and the ball structure 112. In some embodiments, no solder material 110 exists between the UBM structure 106 and the IMC structure 108. Furthermore, the IMC structure 108 is connected to the UBM structure 106.

The IMC structure 108 may be formed of tin, copper, gold, silver, palladium, bismuth, cobalt, geranium, and combinations thereof. The IMC structure 108 may further include compounds such as copper-nickel-tin intermetallic compounds or nickel-tin intermetallic compounds. The IMC structure 108 may directly connect with the UBM structure 106 due to the high-texture material forming the UBM structure 106. The high-texture material of the UBM structure 106 exhibits a fast diffusion rate resulting in a quick, and in some instances an immediate, connection between the IMC structure 108 and the UBM structure 106.

In some embodiments, the degree of connection between the UBM structure 106 and IMC structure 108 may be determined. The degree of connection refers to how well the UBM structure 106 and IMC structure 108 are bonded. For example, the IMC structure 108 may act as a metallurgical bond between the UBM structure 106 and the solder material 110. Therefore, the formation of the IMC structure 108 may impact the overall performance reliability of the semiconductor structure.

The degree of connection between the UBM structure 106 and IMC structure 108 may be determined using SEM, TEM, and other appropriate imaging and analysis techniques. As mentioned above, SEM uses a focused beam of electrons to scan the surface and analyzes reflected beams to create detailed images of the topology of the surface structure. Similarly to SEM, TEM sends a beam of electrons towards a surface, however unlike SEM, the beam of electrons in TEM passes through the surface to create an image of the internal structure. Therefore, TEM may be used to determine the degree of connection between the UBM structure 106 and IMC structure 108 by providing an internal structural image.

In some embodiments, the IMC structure 108 surrounds a ball structure 112. The ball structure 112 may be formed of a conductive material such as copper, tungsten, gold, silver, or other appropriate materials. The ball structure 112 may improve electrical conductivity by enhancing the electrical connection between elements of the semiconductor device. Further, the ball structure 112 may provide improved mechanical strength and reliability within the joint structure resulting in resistance to thermal cycling and mechanical stress. Even further, the ball structure 112 maintains coplanarity of the ball structure 112 and solder material 110 which ensures a reliable connection during the reflow process to form the IMC structure 108.

Additionally, the ball structure 112 mitigates against electromigration. Electromigration occurs when metal atoms move due to high current density leading to device failure. By reducing current crowding and current density, the ball structure 112 mitigates electromigration and enhances overall performance of the semiconductor device.

In some embodiments, the solder material 110 is located above the IMC structure 108. The solder material 110 may be formed of an alloy such as a tin-alloy with lead, silver, copper, and/or other appropriate metals. The solder material 110 may provide an electrical connection between elements within the semiconductor device and further provides mechanical support to secure elements within the semiconductor device.

The UBM structure 106 may ensure the ball structure 112 is fixed during manufacturing and use of the semiconductor device. In other words, the UBM structure 106 creates a cradle like structure to ensure the ball structure 112 is fixed in a centered portion of the UBM structure 106. For example, the UBM structure 106 secures the ball structure 112 to be substantially centered within the UBM structure 106 with the solder material 110 uniformly surrounding the ball structure 112. Therefore, all sides of the solder material 110 surrounding the ball structure 112 are similar in thickness and prevent the solder material 110 from cracking or weakening.

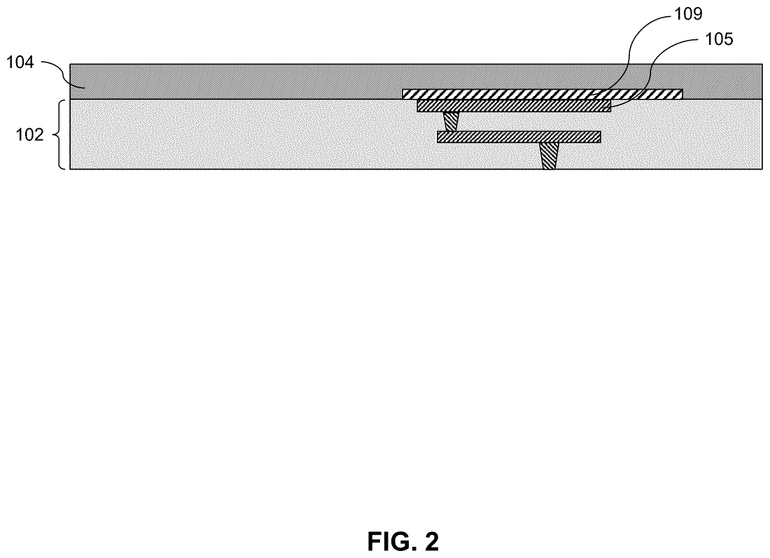

FIGS. 2 through 11 illustrate vertical cross-sectional views of portions of intermediate structures during the formation of the UBM structure 106 and fixed positioned ball structure 112 with a connected IMC structure 108. The UBM structure 106 provides a pedestal-like shape that partially surrounds the ball structure 112 with a recess 140. The shape of the UBM structure 106 surrounds the ball structure and enhances the positioning of the ball structure 112 mounted within the UBM structure 106. Additionally, an IMC structure 108 may be directly connected to the UBM structure 106 and fully surrounds the ball structure 112. The UBM structure 106 and IMC structure 108 fix the position of the ball structure 112 to be evenly surrounded by the solder material 110 and prevents ball structure 112 shifting. The resulting structure improves mechanical strength of the semiconductor device by preventing solder material 110 cracking and weaking while maintaining enhanced performance from the ball structure 112.

FIG. 2. illustrates a polyimide layer 104 located above an RDL 102. The RDL 102 may include a dielectric layer 103 with redistribution wiring interconnects 105 formed within the dielectric layer 103 and bonding pads 109 located above the redistribution wiring interconnects 105. In some embodiments, the bonding pad 109 may be integrated with the redistribution wiring interconnects 105. The RDL 102 may optimize connectivity and improve integration levels by rerouting electrical connections by optimizing connections between elements. Additionally, the RDL 102 may enhance electrical performance by enhancing signal integrity between components.

The polyimide layer 104 may be formed of polyimide, benzocylcobutene, silicon nitride, silicon oxide, or other appropriate materials. The polyimide layer 104 may protect the RDL 102 from contaminants, such as moisture and dust, therefore preventing corrosion and electrical failures. Additionally, the polyimide layer 104 provides mechanical stability to prevent stress during handling and packaging. Further the polyimide layer 104 provides electrical insulation by preventing short circuits between adjacent metal traces and thermal management by dissipating heat away from active regions.

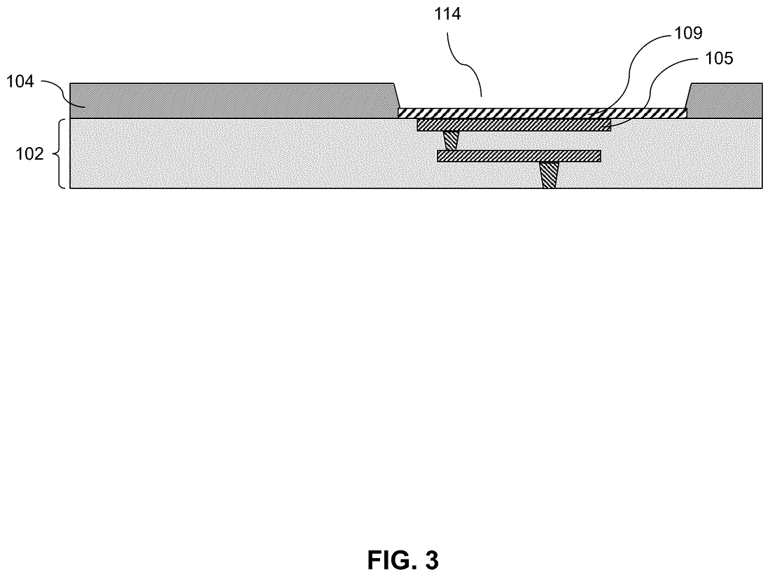

FIG. 3 illustrates forming a cavity 114 within the polyimide layer 104. For example, a photoresist patterning and etching process may form a cavity 114 in the polyimide layer 104. The cavity 114 in the polyimide layer 104 may expose the bonding pad 109 located in the RDL 102.

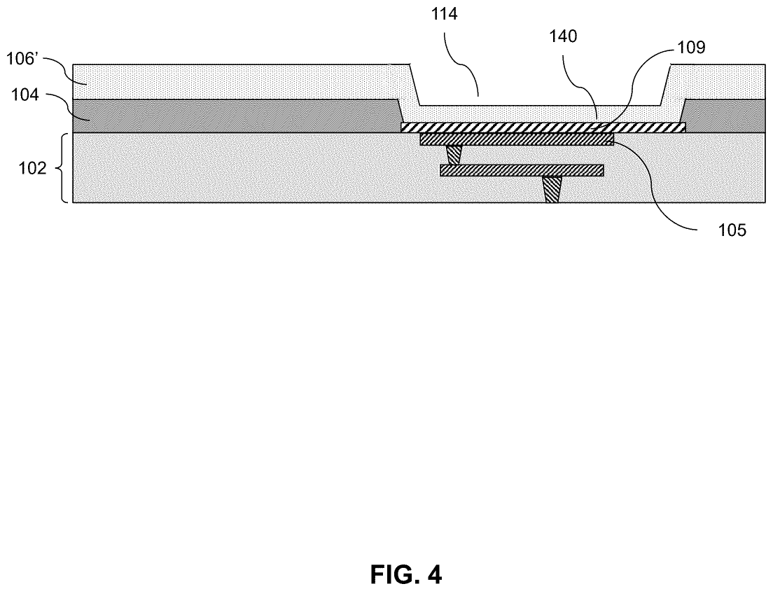

FIG. 4 illustrates a UBM seed layer 106′ deposited above the polyimide layer 104. The UBM seed layer 106′ may include a texture structure, such as Cu(111). Cu(111) may be referred to as a “textured structure”, “textured copper”, “high-texture structure” or “high-texture copper”. A surface of the Cu(111) may be highly textured (e.g., have a high roughness). However, the roughness of the surface may be modified (e.g., by adjusting the parameter of the plating process) to be close to that of a Cu(100) layer (e.g., a non-textured structure) which may have a higher amount of random copper than a Cu(111) layer.

In some embodiments, the UBM seed layer 106′ may be deposited using a sputtering technique. The sputtering technique includes placing the semiconductor structure (e.g., the RDL 102 and polyimide layer 104 structure) in a vacuum chamber with an inert gas, such as argon. The UBM seed layer material (e.g., high-texture copper (111), copper (100), copper (001), or other appropriate high-texture materials) may be placed in the chamber and a negative charge may be applied to the inert gas creating a plasma. The plasma may collide with the UBM seed layer material causing the UBM seed layer material to be deposited onto the polyimide layer 104 and the RDL 102 exposed in the cavity 114 to form the substantially uniform UBM seed layer 106'. The sputtering technique may form a uniform and high-quality UBM seed layer 106′ for other structures and elements to connect and grow upon.

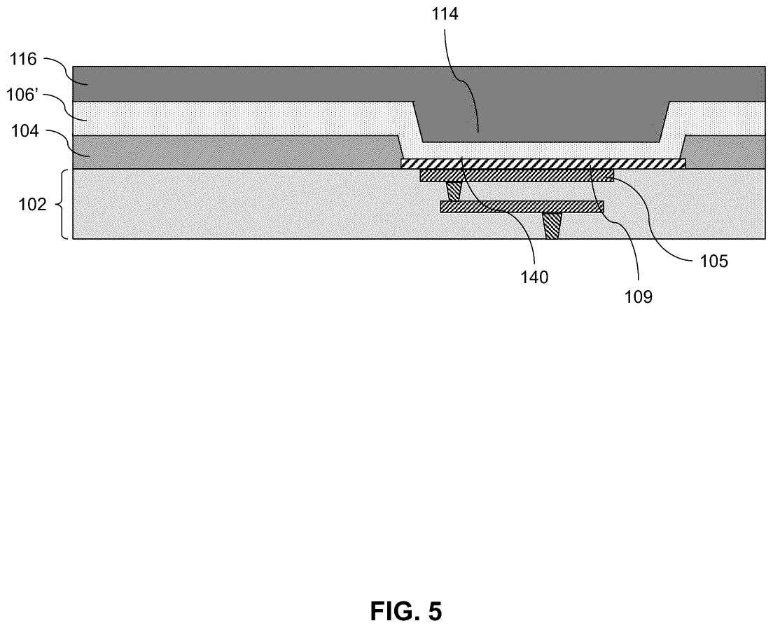

FIG. 5 illustrates an intermediate under-bump metallization structure after depositing a photoresist layer 116 above the UBM seed layer 106′ and in the cavity 114. The photoresist layer 116 is a light-sensitive material used in a photolithography process to form geometric patterns onto a surface. The photoresist layer 116 may be a positive photoresist layer where in the instance the photoresist layer is exposed to light, the photoresist layer 116 becomes soluble to allow the exposed areas to be washed away or a negative photoresist layer where in the instance the photoresist layer 116 is exposed to light, the photoresist layer 116 becomes insoluble and the unexposed areas are washed away. The photoresist layer 116 may be formed of a resin, photoactive compound, and a solvent and optionally dyes for visual inspection or anti-oxidizing agents to enhance stability.

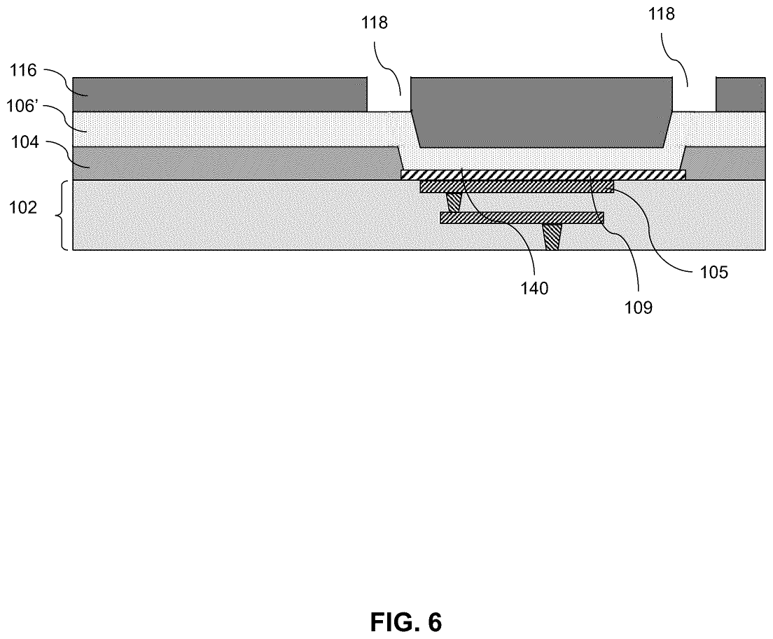

FIG. 6 illustrates the intermediate under-bump metallization structure after patterning and developing the photoresist layer 116. Initially, the photoresist layer 116 may be exposed to light at a specific wavelength (e.g., UV light between 100 nm and 400 nm) through a mask with the desired pattern. In this embodiment and as shown in FIG. 5, the mask may include two sections corresponding to cavities 118 within the photoresist layer 116. The chemical structure of the photoresist layer 116 may be altered in areas exposed to the light beams. The structure may then be developed using a chemical solution which either removes the exposed or unexposed areas based on the type of photoresist material used. For example, a positive photoresist material will wash away the exposed areas while a negative photoresist material will wash away the unexposed areas. The resulting structure includes two cavities 118 in the photoresist layer 116 exposing the UBM seed layer 106'.

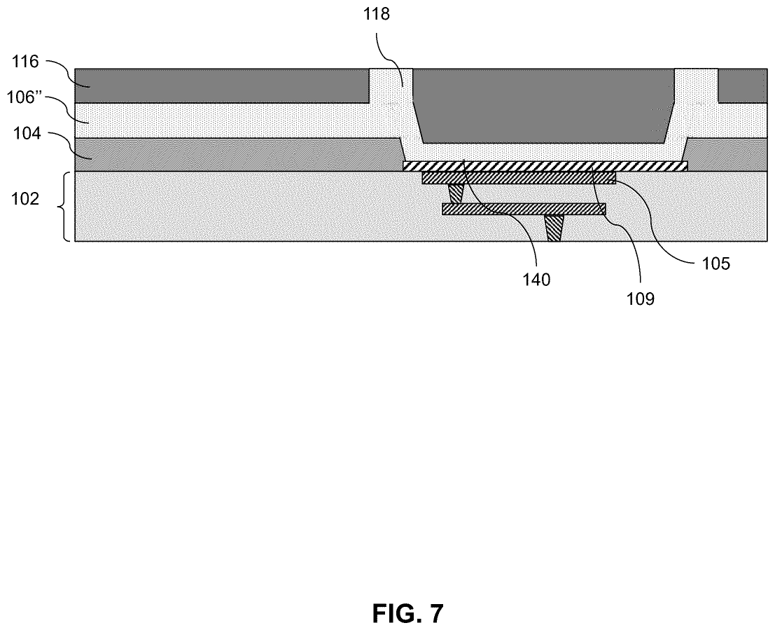

FIG. 7 illustrates the intermediate under-bump metallization structure after plating a high-texture material in the cavities 118. Initially, a thin layer of high-texture material, such as copper with a (111) orientation, may be deposited onto the UBM seed layer 106′ forming an expanded UBM seed layer 106″. In some embodiments, the high-texture material is the same material as the UBM seed layer 106′. The initial thin layer provides a conductive surface for electroplating. The semiconductor structure may then be submerged in an electrolyte bath containing a solution of high-texture material ions, such as copper ions or copper sulfate. An electrical current may be applied causing the high-texture material ions to migrate and deposit onto the thin layer forming a thicker high-texture material layer. After electroplating, the surface may undergo planarization by being polished using a chemical-mechanical polishing process to remove excess ions and achieve a smooth planar surface. The resulting structure includes a high-texture material formed within the cavities 118 connecting to the UBM seed layer 106′ forming an expanded UBM seed layer 106″.

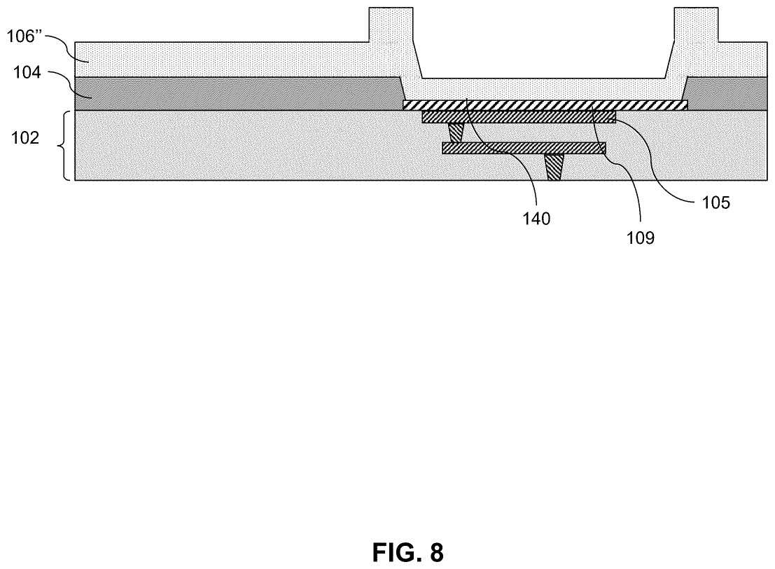

FIG. 8 illustrates the intermediate under-bump metallization structure after stripping the photoresist layer 116 leaving the expanded UBM seed layer 106″. The photoresist layer 116 stripping process may include a wet stripping, a dry stripping, or a combination method. The wet stripping process may use a chemical solution of solvents and/or acids to dissolve and remove the photoresist layer 116. The dry stripping process may use a plasma, such as an oxygen plasma, of ionized gas to break down the photoresist layer 116. The plasma may react with the photoresist layer 116 to form a volatile compound that is then removed. Combination methods include wet stripping and dry stripping to ensure a complete removal by dissolving and breaking down the photoresist layer 116. The resulting semiconductor structure includes the expanded UBM seed layer 106″ and the photoresist layer 116 being removed.

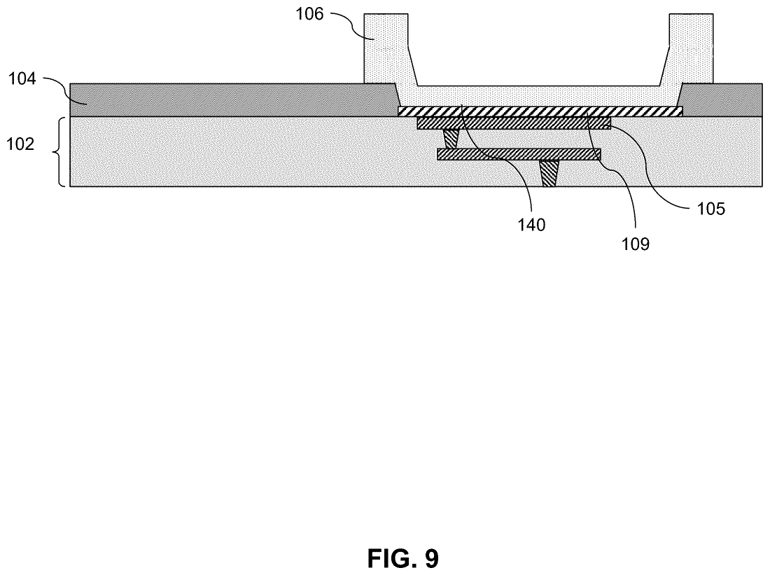

FIG. 9 illustrates the intermediate under-bump metallization structure after etching the expanded UBM seed layer 106″ to form the UBM structure 106. The etching process may be a wet etching process or a dry etching process. In the wet etching process, a chemical solution is applied to portions of the expanded UBM seed layer 106″ to be removed. For example, the portions removed may include the portion of the expanded UBM seed layer 106″ located above the polyimide layer 104 and excluding areas of the UBM seed layer 106″ located in the final UBM structure 106. The chemical solution may include acids and bases that dissolve portions of the expanded UBM seed layer 106″. The dry etching process may use ionized gases such as fluorocarbons, oxygen and chlorine to remove portions of the expanded UBM seed layer 106″. The resulting structure includes the UBM structure 106 formed above the polyimide layer 104 and RDL 102 with a pedestal like shape that includes the recess 140.

In some embodiments, the UBM seed layer 106′, the expanded UBM seed layer 106″, and/or the UBM structure 106 may be analyzed to determine the high-texture material's structure. Methods to analyze the high-texture material may include SEM and EBSD. For example, SEM and EBSD may be used to define the high texture copper with an orientation of (111) after formation of the UBM seed layer 106′, the expanded UBM seed layer 106″, and/or the UBM structure 106. In some instances, the high-texture material may be analyzed and determined after each step, after a subset of steps, or after the final formation of the UBM structure 106.

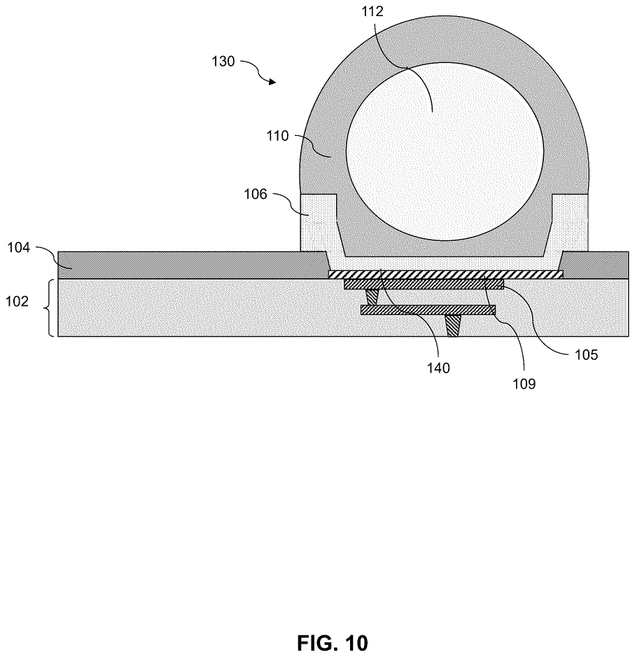

FIG. 10 illustrates the intermediate under-bump metallization structure after mounting the solder ball 130 that includes the solder material 110 with the ball structure 112 above the UBM structure 106. In some embodiments, the ball structure 112 may be formed of a conductive material, such as copper, surrounded by a solder material 110 formed of an alloy such as a tin alloy with other metals such as silver, gold, nickel, copper, palladium, cobalt, bismuth, geranium, and other appropriate alloy metals.

The solder ball 130 may be mounted on the UBM structure 106 by a direct placement method which directly places the solder ball 130 onto the UBM structure 106 using a pick-and-place machine or other appropriate placement methods. The solder ball 130 may be placed in a location substantially aligned with the UBM structure 106 where the ball structure 112 corresponds to the recess 140 of the UBM structure 106.

Additionally, the solder ball 130 may undergo a reflow process and flux cleaning process. In the reflow process, the semiconductor structure may be passed through a reflow oven with different zones. A preheat zone may gradually heat the semiconductor structure to prevent thermal shock. A soak zone may maintain a steady temperature to active flux and remove oxides within the solder material 110. A reflow zone may peak in temperature and melt the solder material 110 to form a connection between the solder material 110 and the UBM structure 106. Lastly, a cooling zone may gradually cool the semiconductor structure to solidify the connection between the solder material 110 and the UBM structure 106.

The reflow process may provide a precise and automated connection process between the solder material 110 and the UBM structure 106 while ensuring high-quality, consistent, and repeatable structures when forming multiple structures within a device. Additionally, the reflow process facilitates mass production of devices by allowing multiple semiconductor structures and/or devices to be produced simultaneously.

Subsequent to the reflow process, the semiconductor structure may undergo a flux cleaning process to remove flux from the solder ball 130. The flux provides good adhesion between the ball structure 112 and the solder material 110 as well as removes oxide materials. However, remaining flux may cause reliability issues, corrosion, or electrical reliability problems and therefore is removed after the reflow process. The flux cleaning process may be a wet cleaning or a dry cleaning. In a wet cleaning, solvents and/or aqueous solutions are applied to dissolve and remove the flux. In a dry cleaning, plasma is applied to remove the flux residue.

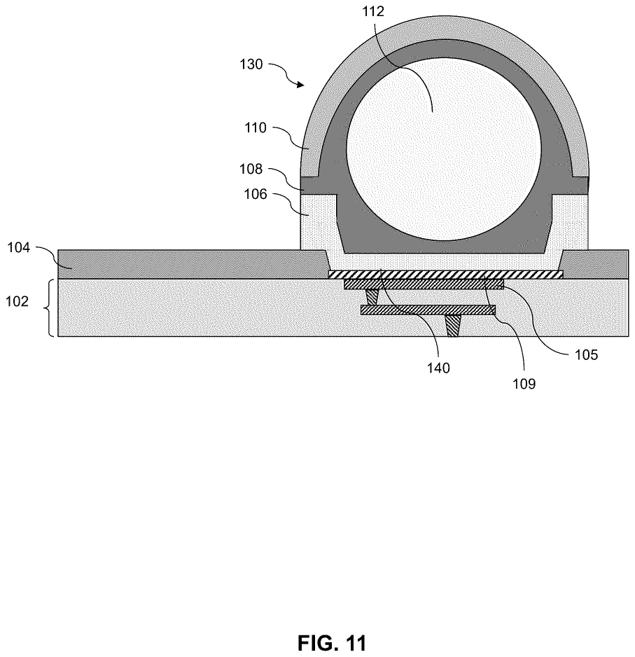

FIG. 11 illustrates the intermediate under-bump metallization structure after an annealing process which forms the IMC structure 108. The annealing process includes heating the semiconductor structure to at least 200° C. to trigger IMC structure 108 formation. Initially, the semiconductor structure is placed in an annealing furnace or a rapid thermal annealing system and the temperature is raised to at least 200° C. At the annealing temperature, different metals in the solder material 110 and the ball structure 112 react to form an IMC structure 108. For example, tin and nickel in the solder material 110 may react with copper in the ball structure 112 to form a tin-copper-nickel alloy with small amounts of gold, silver, palladium, cobalt, bismuth, and geranium. The composition and amount of alloy formed within the IMC structure 108 may be based on temperature and time the semiconductor structure is in the annealing furnace. Due to the high-texture material of the UBM structure 106′ which exhibits a fast diffusion rate, the IMC structure 108 may immediately connect to the UBM structure 106′. In some embodiments, there is a substantially or entirely free nickel-free layer surrounding the ball structure 112.

The semiconductor structure may then be cooled down at a gradual pace to prevent thermal shock. The cooling process may further stabilize the IMC structure 108. The IMC structure 108 may be inspected using SEM and TEM methods to detect the microstructure of the IMC structure 108, including the connection between the IMC structure 108 and the UBM structure 106. The inspection techniques may also determine a degree of connection between the IMC structure 108 and the UBM structure 106.

The annealing process forms the IMC structure 108 above the UBM structure 106 and surrounds the ball structure 112. In some embodiments, the IMC structure 108 is disposed between the UBM structure 106 and the ball structure 112 and also is disposed between the ball structure 112 and the solder material 110. Additionally, the high-texture material that forms the UBM structure 106 exhibits a fast diffusion rate which results in an immediate connection between the UBM structure 106 and the IMC structure 108. The immediate connection between the UBM structure 106 and the ICM structure 108 ensures the ball structure 112 is centered and fixed within the UBM structure 106, therefore preventing drift and mechanical weaknesses.

In some embodiments, the density of the ball structure 112 may be greater than the density of the solder material 110. Therefore, during the annealing process, the ball structure 112 may move towards the UBM structure 106 further fixing the position of the ball structure 112 within the recess 140 of the UBM structure 106. Additionally, the formation of the IMC structure 108 further fixes the position of the ball structure 112. As a result, the ball structure 112 may be located in a fixed location with a substantially equal amount of solder material 110 on each side of the ball structure 112 (e.g., within about 5 μm). Therefore, the fixed position ball structure 112 within the connected IMC structure 108 and UBM structure 106 improves mechanical strength of the semiconductor structure while maintaining enhanced performance of electromigration due to the ball structure 112. Further, the high-texture of the UBM structure 106 prevents side wall wetting and ensures the solder material 110 properly surrounds the ball structure 112.

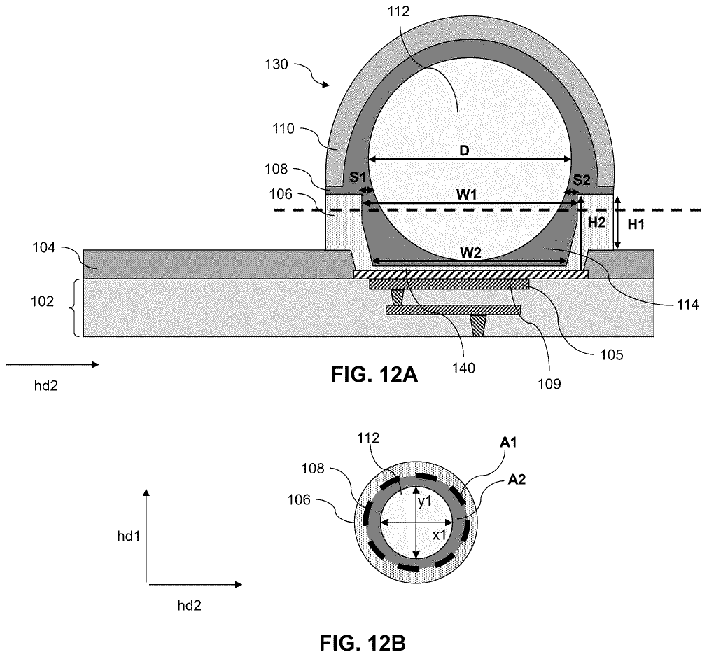

Referring to FIGS. 12A and 12B, various dimensions of the semiconductor structure will be discussed. In some embodiments, a diameter D of the ball structure 112 may be at most 500 μm. The diameter D may be dependent on the bump size by taking into account an amount of solder material 110 desired and/or required to form a stable electrical connection.

A width W1 is defined as the distance of the ball structure 112 and the IMC structure 108 at the top of recess 140. A width W2 may be defined as the width of the bottom of the recess 140 of the UBM structure 106. The width W1 may be greater than the diameter D. The diameter D may be greater than or equal to the width W2. Therefore, the ball structure 112 and surrounding IMC structure 108 may be properly secured and connected to the UBM structure 106. The proper securement and connection may provide and improved mechanical strength of the ball structure 112 while maintaining enhanced performance.

In some embodiments, the first height H1 may be measured from the top surface of the UBM structure 106 to the top surface of the polyimide layer 104. The first height H1 of the UBM structure 106 may be at least about 5 μm and will not exceed 50 μm. The first height H1 of the UBM structure 106 provides structure and stability to the semiconductor structure without being too large which results in mechanical weakening. In other words, the first height H1 of the UBM structure includes a balance between stability of the structure while reducing mechanical weakening.

A second height H2 may be measured from the top surface of the UBM structure 106 to the top surface of the bonding pad 109. The second height H2 may be greater than or equal to the first height H1. Further, the diameter D of the ball structure 112 may be less than or equal to ten times the first height H1.

A first side portion S1 may be defined as the distance between a left boundary of the IMC structure 108 and a left boundary of the ball structure 112. Similarly, a second side portion S2 may be defined as a distance between a right boundary of the ball structure 112 and a right boundary of the IMC structure 108. In some embodiments, the difference between a first side portion S1 of the IMC structure 108 surrounding the ball structure 112 and a second side portion S2 of the IMC structure 108 surrounding the ball structure 112 is at most 5 μm. Therefore, ensuring the solder material 110 is substantially evenly distributed around the ball structure 112. Therefore, the UBM structure 106 has a pedestal like structure with a central recess 140 to ensure proper placement and alignment of the ball structure 112 with evenly surrounding solder material 110. The evenly distributed solder material 110 prevents cracking and weakening of the solder material 110 and therefore improves mechanical strength of the solder ball 130 and overall semiconductor structure.

As shown in FIG. 12B, during the annealing process, a disconnection region A1 between the IMC structure 108 and the UMB structure 106 may be formed. The disconnection portion A1 is filled with either solder material or voids. The disconnection portion A1 is a region that interrupts the IMC structure 108 from fully connecting with the UBM structure 106. A connected IMC portion A2 may represent the areas in which the IMC structure 108 fully and directly connects with the UBM structure. In some embodiments, the connected IMC portion A2 is slightly larger than the disconnection portion A1. In some embodiments, a ratio between the disconnect portion A1 and the connected IMC portion A2 may be at least 0.95. In other words, more of the IMC structure 108 is connected to the UBM structure 106 than is not connected. Therefore, there is proper connection between the IMC structure 108 and the UBM structure 106 further promoting a fixed placement of the ball structure 112. The degree of connection of the IMC 108 structure and the UBM structure 106 may be analyzed and determined by using SEM and EBSD.

Further, the ball structure 112 may be substantially spherical. In other words the major diameter x1 of the ball structure 112 is substantially equivalent to the minor diameter y1 of the ball structure 112. Therefore, the connecting IMC structure 108 is further substantially spherical surrounding the ball structure 112. However, some embodiments may us a ball structure 112 that is more elliptical, oval, or spheroid in shape in which a major diameter x1 is greater that minor diameter y2 (or vice versa).

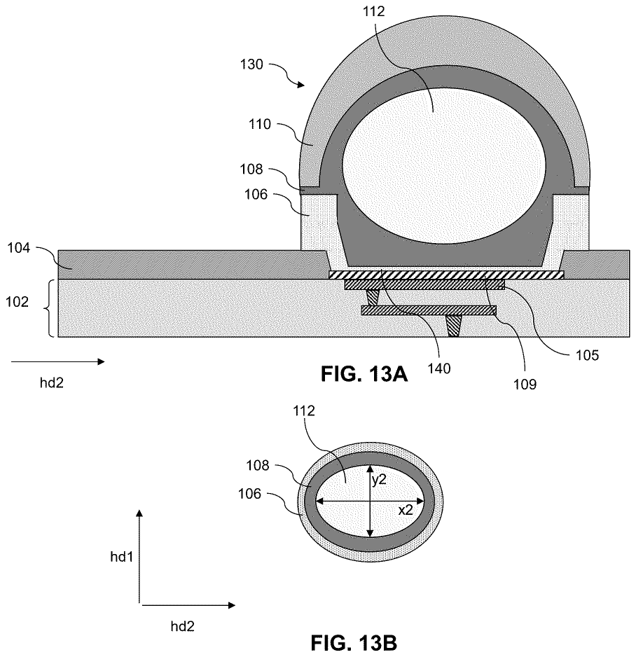

FIGS. 13A and 13B illustrate an alternative embodiment of the ball structure 112. As shown, the ball structure 112 has an oval shape compared to the spherical shape shown in FIGS. 12A and 12B. In other words, a major diameter x2 of the ball structure 112 is larger than a minor diameter y2 of the ball structure 112. The oval ball structure 112 may further exhibit improved electromigration performance to the semiconductor structure. Additionally, the oval ball structure 112 may be based on the desired solder ball shape and size to appropriately connect various elements.

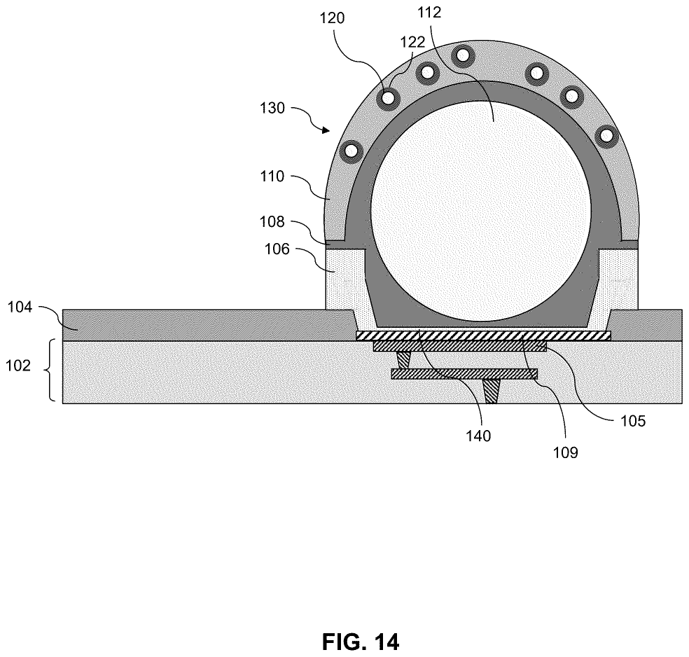

FIG. 14 further illustrates another alternative embodiment of the semiconductor structure. As shown, the semiconductor structure includes a primary ball structure 112 surrounded by the IMC structure 108 connected to the UBM structure 106. Additionally, as shown, a plurality of bead structures 120 surrounded by corresponding IMC structures 122 are located within the solder material 110. In some embodiments, each bead structure 120 may be substantially the same size and shape. In other embodiments, each bead structure 120 may differ in size and shape. The corresponding IMC structures 122 size and shape are based on the size and shape of the bead structures 120. The additional bead structures 120 may exhibit improved electromigration performance because the bead structures 120 distribute the current more evenly within the solder material 110 and therefore mitigates electromigration failures.

The following discussion now refers to a number of methods and method acts. Although the method steps are discussed in specific orders or are illustrated in a flow chart as being performed in a particular order, no order is required unless expressly stated or required because a step is dependent on another step being completed prior to the step being performed.

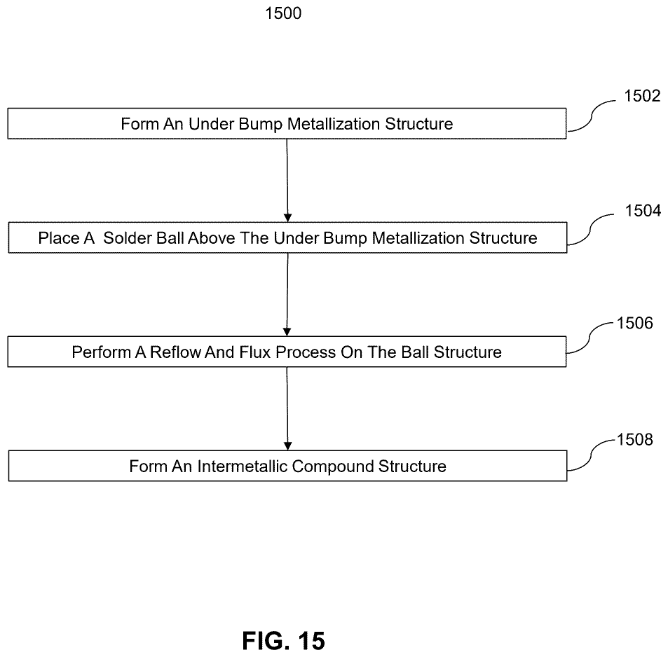

Embodiments are now described in connection with FIG. 15, which illustrates a flow diagram of example method 1500 for forming a UBM structure 106 and solder ball 130 with a connected IMC structure 108, according to an embodiment of the present disclosure. In an embodiment, step 1502 in method 1500 comprises forming a UBM structure 106 above a polyimide layer 104. Referring to FIGS. 1 and 4-9, the UBM structure 106 is formed above a polyimide layer 104 and a portion of an RDL layer 102. The UBM structure 106 may have a pedestal like structure with a center recess 140. In some embodiments, the UBM structure 106 is formed of a high-texture material such as copper with a (111) orientation.

In an embodiment, step 1504 in method 1500 comprises placing a solder ball 130 above the UBM structure 106. Referring to FIGS. 1 and 10, the solder ball 130 is placed directly above the UBM structure 106. The solder ball 130 may include a ball structure 112 and a solder material 110. Additionally, the ball structure 112 may be substantially aligned above the recess 140. The pedestal like shape of the UBM structure 106 with the recess 140 creates an alignment structure for the ball structure 112 to ensure the solder material 110 evenly surrounds the ball structure 112 and therefore results in improved mechanical strength of the semiconductor structure. Therefore, the UBM structure 106 reduces ball structure 112 shifting and solder material 110 mechanical weaknesses while maintaining enhanced performance due to the crowd current properties of the ball structure 112.

Step 1506 in method 1500 comprises performing a reflow and flux process on the solder ball 130. Referring to FIGS. 1 and 10, the solder ball 130 may undergo a reflow process which connects the solder material 110 to the UBM structure 106. Additionally, the flux process may clean away any flux used in the reflow process from the ball structure 130. Due to the UBM structure 106 being formed of a high texture material, such as copper with a (111) orientation, the UBM structure 106 prevents side wall wetting and ensures the solder material 110 surrounds the ball structure 112 properly. Therefore, the UBM structure 106 prevents solder material 110 cracking and mechanical weaknesses and therefore improving mechanical strength of the solder ball 130.

In an embodiment, step 1508 in method 1500 comprises forming, by an annealing process, an IMC structure 108 located above the UBM structure 106 and between the ball structure 112 and the solder material 110. Referring to FIGS. 1 and 11, an annealing process triggers the formation of the IMC structure 108. In some embodiments, the annealing process occurs at a temperature of at least 200° C. The annealing process may trigger compounds from the ball structure 112 and the solder material 110 to react and form an IMC structure 108 formed of an alloy, such as tin, copper, and nickel with additional small amounts of other metals. Due to the UBM structure 106 being formed of a high texture material, such as copper with a (111) orientation, the IMC structure 108 immediately connects to the UBM structure 106 during the annealing process. Therefore, the connected UBM structure 106 and IMC structure 108 further fix the position of the ball structure 112 to prevent shifting and improve mechanical strength of the solder ball 130.

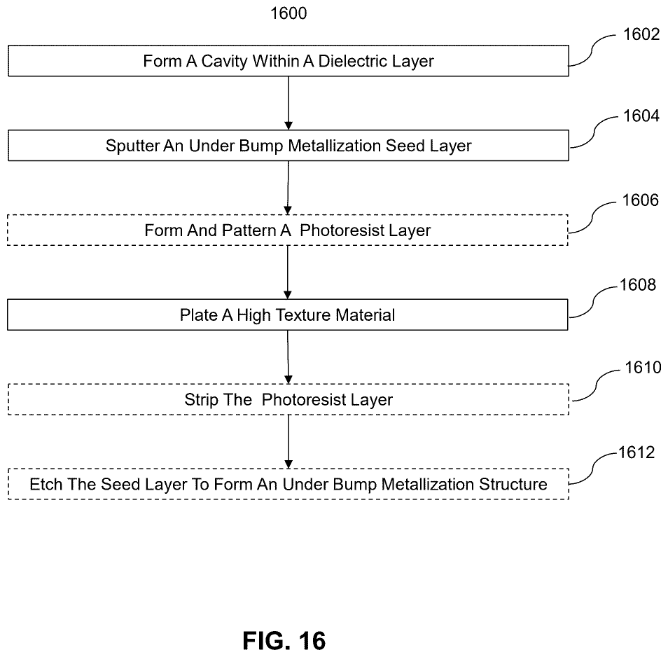

Embodiments are now described in connection with FIG. 16, which illustrates a flow diagram of example method 1600 for forming a UBM structure 106, according to an embodiment of the present disclosure. In an embodiment, step 1602 in method 1600 comprises forming a cavity 114 within a dielectric layer 104. Referring to FIGS. 1-3, a cavity 114 is etched within the dielectric layer 104 exposing a portion of the RDL 102. The cavity 114 may further be polished using a chemical mechanical polishing process.

In an embodiment, step 1604 includes sputtering a UBM seed layer 106′ above the dielectric layer 104. Referring to FIGS. 1 and 4, the UBM seed layer 106′ is deposited above the dielectric layer 104 and exposed portion of the RDL 102 within the cavity 114. In an embodiment, the UBM seed layer 106′ above the RDL 102 forms a recess 140 portion. The UBM seed layer 106′ may be formed of a high texture material such as copper with a (111) orientation. The height of the UBM seed layer 106′ may be at least 5 μm and will not exceed 50 μm to provide structure and stability to the semiconductor structure without being too large which results in mechanical weakening. Therefore, the height of the UBM seed layer 106′ provides a balance between structural stability and mechanical weaknesses.

Optionally, in an embodiment, step 1606 comprises forming and patterning a photoresist layer 116 above the UBM seed layer 106′. The photoresist layer 116 may be a positive photoresist layer or a negative photoresist layer. Additionally, the patterning uses a pattern to form cavities 118 within the photoresist layer 116.

In an embodiment, step 1608 comprises plating a high texture material above the UBM seed layer 106′ to form the UBM structure 106″. Referring to FIGS. 1 and 7, the high texture material is plated within the cavities 118 within the patterned photoresist layer 116 to form the UBM structure 106″. The high texture material may be copper with a (111) orientation similar to the UBM seed layer 106′. Further, the high texture material may be plated using electroplating techniques or other appropriate plating techniques. In some embodiments, the surface may be cleaned or etched so that the plated high texture material 106″ is planar with the photoresist layer 116 in the cavities 118.

Optionally, in an embodiment, step 1610 comprises stripping the photoresist layer 116. Referring to FIGS. 1 and 8, once the cavities 118 within the photoresist layer 116 are plated with the high texture material to form the UBM seed layer 106″, the photoresist layer 116 may be stripped. The stripping process may include a wet stripping or a dry stripping. In some embodiments, the surface may further be cleaned post stripping the photoresist layer 116.

Optionally, in an embodiment, step 1612 comprises etching the UBM seed layer 106″ to remove a portion of the UBM seed layer 106″ above the dielectric layer 104 and leaving behind the final UBM structure 106. Referring to FIGS. 1 and 9, the seed layer 106″ above the dielectric layer 104 not directly forming the UBM structure 106 may be removed by a dry or wet etching process. The result is the UBM structure 106 that provides a connection structure for the solder ball 130 and eventual IMC structure 108 therefore providing mechanical strength to the semiconductor structure. The resulting UBM structure 106 includes a recess 140 to align the ball structure 112 and ensure the solder material 110 uniformly surrounds the ball structure 112 to prevent cracking and mechanical weaknesses.

Referring to all drawings and according to various embodiments of the present disclosure, a semiconductor structure, including a redistribution layer 102, a polyimide layer 104 located above the redistribution layer 102, a UBM structure 106 extending through the polyimide layer 104 and in contact with the redistribution layer 102, wherein the UBM structure 106 includes a recess 140, a ball structure 112 located above the recess 140 of the UBM structure 106, an IMC structure 108 located above and connected to the UBM structure 106 and surrounding the ball structure 112, and a solder portion 110 located above the IMC structure 108, such that between the IMC structure 108 and the UBM structure 106 is free of the solder material 110.

In some embodiments, the UBM structure 106 is formed of a high texture material. In some embodiments, the high texture material is one of copper material with a (111) orientation, aluminum, gold, or silver. In some embodiments, the ball structure 112 has a width substantially equal to a height. In some embodiments, the ball structure 112 has a width that is larger than a height. In some embodiments, the semiconductor structure further includes a plurality of bead structures 120 located within the solder portion 110, wherein each bead structure 120 is surrounded by an IMC structure 122. In some embodiments, a first height H1 of the UBM structure 106 is at least 5 μm and at most 50 μm. In some embodiments, a ratio between a disconnection portion A1 located between the solder material 110 and the IMC structure 108 to a connected IMC portion A2 is at least 0.95. In some embodiments, more of the UBM structure 106 is connected to the IMC structure 108 than portions of the UBM structure 106 are disposed away from the IMC structure 108 due to interrupting voids or solder material 110. In some embodiments, a difference between a first side portion S1 of the IMC structure 108 surrounding a side of the ball structure 112 and a second side portion S2 of the IMC structure 108 surrounding an opposite side of the ball structure 112 is less than 5 μm. In some embodiments, a second height H2 of the UBM structure 106 is greater than or equal to a first height H1 of the UBM structure 106 and the diameter D of the ball structure 112 is less than or equal to ten times the first height H1 of the UBM structure 106. In some embodiments, a width W of the ball structure 112 and IMC structure 108 is greater than a diameter D of the ball structure 112 and the diameter of the ball structure 112 is greater than or equal to a width W2 of the recess 140. In some embodiments, a diameter of the ball structure 112 is at most 500 μm.

In another embodiment, a method for forming a UBM structure 106 with a solder ball 130 and an IMC structure 108, includes forming a UBM structure 106 above a polyimide layer 104, wherein the UBM structure 106 includes a recess 140, placing a solder ball 130 above the UBM structure 106, wherein the solder ball 130 includes a ball structure 112 surrounded by a solder material 110 and the ball structure 112 is located above the recess 140, and annealing the UBM structure 106, solder material 110 and ball structure 112 to form an IMC structure 108 located above the UBM structure 106 and between the ball structure 112 and the solder material 110 such that between the IMC structure 108 and the UBM structure 106 is free of the solder material 110.

In some embodiments, the method further includes performing a reflow and flux process on the solder ball 130. In some embodiments, forming the IMC structure 108 includes a disconnection region A1 located between the IMC structure 108 and the solder portion 110 and wherein a ratio between a disconnection portion A1 located between the UBM structure 106 and the IMC structure 108 and a connected IMC portion A2 is at least 0.95. In some embodiments, forming the IMC structure 108 immediately connects with the IMC structure 108 with the UBM structure 106. In some embodiments, forming the IMC structure 108 causes the ball structure 112 to move toward the UBM structure 106.

In another embodiment, a method for forming an UBM structure 106 includes forming a cavity 114 within a dielectric layer 104, sputtering a UBM seed layer 106′ above the dielectric layer 104, and plating a high texture material above the UBM seed layer 106′ to form UBM structure 106.

In some embodiments, plating the high texture material further includes forming and patterning a photoresist layer 116 above the UBM seed layer 106′, plating the high-texture material within the patterned photoresist layer 116, and stripping the photoresist layer 116. In some embodiments, the method further includes etching the UBM seed layer 106″ to remove a portion of the UBM seed layer 106″ above the dielectric layer 104.

Various embodiments disclosed herein may provide various advantages and improvements. For example, various embodiments disclosed herein may provide a under-bump metallization structure that ensures a uniform balls structure shape. Additionally, the under-bump metallization structure may improve alignment between the under-bump metallization and the ball structure. Further, various embodiments enhance the performance of electromigration due to the ball structure reducing current crowding. Additionally, the under-bump metallization structure provides additional mechanical strength to reduce cracking and fracturing of the solder ball structure. Various embodiments disclosed may further utilize a high-texture material to form the under ball materialization which prevents side wall wetting and ensure the solder material surrounds the conductive portion of the ball structure. The high-texture material also may exhibit faster diffusion rate resulting in immediate connection between the under-bump metallization and the intermetallic compound structure. Therefore, various embodiments disclosed herein improve semiconductor structure reliability in particular improving mechanical strength.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a redistribution layer;
a polyimide layer located above the redistribution layer;
an under-bump metallization structure extending through the polyimide layer and in contact with the redistribution layer, wherein the under-bump metallization structure includes a recess;
a ball structure located above the recess of the under-bump metallization structure;
an intermetallic compound structure located above and connected to the under-bump metallization structure and surrounding the ball structure; and
a solder material located above the intermetallic compound structure, such that between the intermetallic compound structure and the under-bump metallization structure is free of the solder material.

2. The semiconductor structure of claim 1, wherein the under-bump metallization structure is formed of a high texture material.

3. The semiconductor structure of claim 2, wherein the high texture material is one of copper material with a (111) orientation, aluminum, gold, or silver.

4. The semiconductor structure of claim 1, wherein the ball structure has a major diameter substantially equal to a minor diameter.

5. The semiconductor structure of claim 1, wherein the ball structure has a major diameter that is larger than a minor diameter.

6. The semiconductor structure of claim 1, further comprising a plurality of bead structures located within the solder material, wherein each bead structure is surrounded by a corresponding intermetallic compound structure.

7. The semiconductor structure of claim 1, wherein a first height of the under-bump metallization structure is at least 5 μm and at most 50 μm.

8. The semiconductor structure of claim 1, wherein a ratio between a disconnection portion located between the under bump metallization structure and the intermetallic compound structure and a connected intermetallic compound portion is at least 0.95.

9. The semiconductor structure of claim 1, wherein a difference between a first side portion of the intermetallic compound structure surrounding a side of the ball structure and a second side portion of the intermetallic compound structure surrounding an opposite side of the ball structure is less than 5 μm.

10. The semiconductor structure of claim 1, wherein a second height of the under-bump metallization structure is greater than or equal to a first height of the under-bump metallization structure; and wherein a diameter of the ball structure is less than or equal to ten times the first height of the under-bump metallization structure.

11. The semiconductor structure of claim 1, wherein a width of the ball structure and intermetallic compound structure is greater than a diameter of the ball structure, and wherein the diameter of the ball structure is greater than or equal to a width of the recess.

12. The semiconductor structure of claim 1, wherein a diameter of the ball structure is at most 500 μm.

13. A method for forming an under-bump metallization structure with a solder ball and an intermetallic compound structure, comprising:
forming an under-bump metallization structure above a polyimide layer, wherein the under-bump metallization structure includes a recess;
placing a solder ball above the under-bump metallization structure, wherein the solder ball includes a ball structure surrounded by a solder material and the ball structure is located above the recess; and
annealing the under-bump metallization structure, solder material and ball structure to form an intermetallic compound structure located above the under-bump metallization structure and between the ball structure and the solder material such that between the intermetallic compound structure and the under-bump metallization structure is free of solder material.

14. The method of claim 13, further comprising performing a reflow and flux process on the solder ball.

15. The method of claim 13, wherein annealing the under-bump metallization structure forms a disconnection portions comprising voids and solder material portions located between the intermetallic compound structure and the under-bump metallization structure and a connected intermetallic compound portion; and wherein a ratio between a disconnection portion located between the under bump metallization structure and the intermetallic compound structure and a connected intermetallic compound portion is at least 0.95.

16. The method of claim 13, wherein forming the intermetallic compound structure immediately connects with the intermetallic compound structure with the under-bump metallization structure.

17. The method of claim 13, wherein forming the intermetallic compound structure causes the ball structure to move toward the under-bump metallization structure.

18. A method for forming an under-bump metallization structure, comprising:
forming a cavity within a dielectric layer;
sputtering a seed layer above the dielectric layer; and
plating a high texture material above the seed layer to form the under-bump metallization structure.

19. The method of claim 18, wherein plating the high texture material further comprises:
forming and patterning a photoresist layer above the seed layer; and
plating the high-texture material within the patterned photoresist layer.

20. The method of claim 18, further comprising etching the seed layer to remove a portion of the seed layer above the dielectric layer.
